(19) United States
(12) Patent Application Publication
(10) Pub. No.: US 2025/0199488 A1
(43) Pub. Date: Jun. 19, 2025

(54) OPTIMIZATION CONTROL METHOD FOR INTEGRATED ENERGY SYSTEM BASED ON PHYSICAL-INFORMED NEURAL NETWORK

(71) Applicant: ZHEJIANG UNIVERSITY, Hangzhou (CN)

(72) Inventors: Xiaojie LIN, Hangzhou (CN); Chongshuo YUAN, Hangzhou (CN); Wei ZHONG, Hangzhou (CN); Yanling WU, Hangzhou (CN); Yi ZHOU, Hangzhou (CN)

(21) Appl. No.: 18/948,572

(22) Filed: Nov. 15, 2024

Related U.S. Application Data
(63) Continuation of application No. PCT/CN2024/095391, filed on May 27, 2024.

(30) Foreign Application Priority Data
Dec. 18, 2023 (CN) 202311738768.4

(51) Int. Cl. G05B 13/02; G05B 13/04; G06Q 50/06

(52) U.S. Cl. CPC G05B 13/027; G05B 13/042; G06Q 50/06

(57) ABSTRACT

The present disclosure discloses an optimization control method for an integrated energy system based on a physical-informed neural network, which comprises the following steps: S1, constructing an a solar-electricity-heat-gas integrated energy system optimization control model; S2, generating a node connection relation matrix based on the network topology structure of the integrated energy system; S3, constructing a deep graph neural network model with physical-informed fusion; S4, constructing a loss function of the deep graph neural network model with physical-informed fusion; and S5, training a physical-informed neural network model according to the historical operation data to be used for system optimization control. The present disclosure can effectively deal with the influence of uncertainty of renewable energy and unexpected situations on the energy system, thereby ensuring the safe and stable operation of the integrated energy system.

### CROSS-REFERENCE TO RELATED APPLICATIONS

The present application is a continuation of International Application No. PCT/CN2024/095391, filed on May 27, 2024, which claims priority to Chinese Application No. 202311738768.4, filed on Dec. 18, 2023, the contents of both of which are incorporated herein by reference in their entireties.

### TECHNICAL FIELD

The present disclosure belongs to the field of optimization control of an integrated energy system, and in particular, to an optimization control method for an integrated energy system based on a physical-informed neural network.

### BACKGROUND

With the background of the current carbon peaking and carbon neutrality goals, the construction and operation of integrated energy systems are facing unprecedented challenges and opportunities. Deep integration of renewable energy into integrated energy system is an effective measure to reduce carbon emissions, and how to effectively manage the system containing renewable energy has become an urgent problem. In addition, the frequent accidents caused by the aging of infrastructure also bring new uncertainties to the stable operation of the integrated energy system. However, the long response time of traditional optimization methods can hardly meet the current control requirements.

### SUMMARY

In view of the problems existing in the prior art, the present disclosure provides an optimization control method for an integrated energy system based on a physical-informed neural network. A deep graph neural network model with physical-informed fusion is constructed by incorporating the optimization target of the system and variable constraint conditions into the loss function of the deep graph neural network. In the process of control optimization, a trained neural network model can provide the system control strategy in real time to ensure that the system is in the best state, which can effectively deal with the uncertainty of renewable energy and the impact of unexpected situations on the energy system, and ensure the safe and stable operation of the integrated energy system.

The present disclosure is implemented by adopting the following technical solution:

An optimization control method for an integrated energy system based on a physical-informed neural network includes the following steps:
S1, constructing a solar-electricity-heat-gas integrated energy system optimization control model.
S2, generating a node connection relation matrix based on a network topology structure of the integrated energy system.
S3, constructing a deep graph neural network model with physical-informed fusion based on the solar-electricity-heat-gas integrated energy system optimization control model constructed in the step S1 and the node connection relation matrix constructed in the step S2.
S4, constructing a loss function of the deep graph neural network model with physical-informed fusion.
S5, training the deep graph neural network model with physical-informed fusion according to historical operation data and performing optimization control for the integrated energy system by using the trained deep graph neural network model with physical-informed fusion.

Further, the step S1 of constructing a solar-electricity-heat-gas integrated energy system optimization control model includes the following sub-steps:
S11, a power generation model of a photovoltaic device and corresponding constraint conditions are established:

$${P}_{PV} ( t ) = G ( t ) A {η}_{PV} {η}_{inv}$$

where P_{PV}(t) represents a generated power of the photovoltaic device at a current moment; G(t) represents a illuminance at the current moment; A represents a photovoltaic panel area; and η_{PV} and ηᵢₙᵥ represent a photovoltaic panel efficiency and an inverter efficiency, respectively;

$$0 < {P}_{PV} ( t ) < {P}_{PV , max}$$

where P_{PV,max} represents the upper limit of the generated power of the photovoltaic device.
S12, an output model of a cogeneration device is established, further includes the following sub-sub-steps:
S121, a power model (including a power generation model and an output thermal power model) of a gas turbine and the corresponding constraint conditions are established:

The power generation model and corresponding constraint conditions are as follows:

$${P}_{GT} ( t ) = {G}_{GT} ( t ) {q}_{NG} {η}_{GT}$$

where P_{GT}(t) represents a generated power of the gas turbine at a current moment; G_{GT}(t) represents a natural gas flow into the gas turbine at the current moment; q_{NG} represents a low calorific value of natural gas; and η_{GT} represents a power generation efficiency of the gas turbine;

$${P}_{GT , min} < {P}_{GT} ( t ) < {P}_{GT , max}$$

where P_{GT,max} and P_{GT,min} represent the upper and lower limits of the generated power of the gas turbine, respectively.

The output thermal power model and corresponding constraint conditions are:

$${Q}_{GT ( t )} = {G}_{G T} ( t ) {q}_{NG} ( 1 - {η}_{GT} )$$

where Q_{GT}(t) represents the output thermal power of the gas turbine at the current moment;

$${Q}_{GT , min} < {Q}_{GT} ( t ) < {Q}_{GT , max}$$

where Q_{GT,max} and Q_{GT,min} represent the upper and lower limits of the output thermal power of the gas turbine, respectively.
S122, a thermal power model of a waste heat boiler and the corresponding constraint conditions are established:

$${Q}_{HRSG} ( t ) = {Q}_{GT} ( t ) {η}_{HRSG}$$

where Q_{HRSG}(t) represents an output thermal power of the waste heat boiler at a current moment; and η_{HRSG} represents a heat exchange efficiency of the waste heat boiler;

$${Q}_{HRSG , min} < {Q}_{HRSG} ( t ) < {Q}_{HRSG , max}$$

where Q_{HRSG,max} and Q_{HRSG,min} represent the upper an lower limits of the output thermal power of the waste heat boiler, respectively.
S13, a thermal power model of an electric boiler and the corresponding constraint conditions are established:

$${Q}_{EB} ( t ) = {P}_{EB} ( t ) {η}_{EB}$$

where Q_{EB}(t) represents an output thermal power of the electric boiler at a current moment; P_{EB}(t) represents the electric power consumed by the electric boiler at the current moment; and η_{EB} represents an electrothermal conversion efficiency of the electric boiler;

$${Q}_{EB , min} < {Q}_{EB} ( t ) < {Q}_{EB , max}$$

where Q_{EB,max} and Q_{EB,min} represent the upper and lower limits of the output thermal power of the electric boiler, respectively.
S14, a thermal power model of a gas boiler and the corresponding constraint conditions are established:

$${Q}_{GB} ( t ) = {G}_{GB} ( t ) {q}_{NG} {η}_{GB}$$

where Q_{GB}(t) represents an output thermal power of the gas boiler at a current moment; G_{GB}(t) represents a natural gas flow into the gas boiler at the current moment; and η_{GB} represents the gas-heat conversion efficiency of the gas boiler;

$${Q}_{GB , min} < {Q}_{GB} ( t ) < {Q}_{GB , max}$$

where Q_{GB,max} and Q_{GB,min} represent the upper and lower limits of the output thermal power of the gas boiler, respectively.
S15, a thermal power model of a heat exchanger and the corresponding constraint conditions are established:

$${Q}_{HE} ( t ) = {Q}_{HE}^{′} ( t ) {η}_{H}$$

where Q_{HE}(t) represents an output thermal power of the heat exchanger at a current moment; Q′_{HE}(t) represents tan input thermal power of the heat exchanger at the current moment; and η_{H} represents a heat exchange efficiency of the heat exchange device;

$${Q}_{HE , min} < {Q}_{HE} ( t ) < {Q}_{HE , max}$$

where Q_{HE,max} and Q_{HE,min} represent the upper and lower limits of the output thermal power of the heat exchanger, respectively.
S16, an electric energy storage model of a storage battery and the corresponding constraint conditions are established:

$$S O C ( t ) = S O C ( t - 1 ) + {η}_{c} {P}_{char} ( t ) - \frac{{P}_{dis} ( t )}{{η}_{d}}$$

where SOC(t) and SOC(t−1) represent the capacities of the battery at a current moment and a last moment, respectively; P_{char}(t) and P_{dis}(t) represent the charging and discharging powers of the storage battery, respectively; and η_{c} and η_{d} represent the charging and discharging efficiencies of the storage battery, respectively;

$$S O {C}_{min} < S O C ( t ) , S O C ( t - 1 ) < S O {C}_{max}$$

$${P}_{SOC , min} < {P}_{char} , {P}_{dis} < {P}_{SOC , max}$$

$${P}_{char} {P}_{dis} ( t ) = 0$$

where SOCₘₐₓ and SOCₘᵢₙ represent the upper and lower limits of the capacity of the storage battery, respectively, and P_{SOC,max} and P_{SOC,min} represent the upper and lower limits of the charging and discharging powers of the storage battery, respectively.
S17, an equilibrium equation of each energy flow network is established, further including the following sub-sub-steps:
S171, a power equilibrium equation of a power grid is established:

$${P}_{PV} ( t ) + {P}_{GT} ( t ) + {P}_{dis} ( t ) + {P}_{E} ( t ) = {L}_{E} ( t ) + {P}_{EB} ( t ) + {P}_{char} ( t )$$

where P_{E}(t) represent the electric power exchange between the integrated energy system and a superior power grid, and its value is positive when the integrated energy system purchases electricity from the power grid, and otherwise it is negative; and L_{E}(t) represents the electric power provided by the integrated energy system to users.
S172, a power equilibrium equation of a heat supply network is established:

$${Q}_{HRSG} ( t ) + {Q}_{EB} ( t ) + {Q}_{GB} ( t ) = \frac{{L}_{H} ( t )}{{η}_{H}}$$

where L_{H}(t) represents a thermal power provided by the integrated energy system to users.
S173, a flow equilibrium equation of a gas network is established:

$${G}_{GT} ( t ) + {G}_{GB} ( t ) + {L}_{NG} ( t ) = {G}_{NG} ( t )$$

where L_{NG}(t) represents a natural gas flow provided by the integrated energy system to users; and G_{NG}(t) represents the flow of natural gas purchased by the integrated energy system from a natural gas company.
S18, branch constraint conditions of the integrated energy system are established:

$$0 < {P}_{br} ( t ) < {P}_{br , max} \\ 0 < {Q}_{br} ( t ) < {Q}_{br , max} \\ 0 < {G}_{br} ( t ) < {G}_{br , max}$$

where P_{br}(t), Q_{br}(t) and G_{br}(t) represent the electric power, thermal power and natural gas flow of any branch at the current moment, respectively; and P_{br,max}, Q_{br,max} and G_{br,max} represent the upper limits of the electric power, thermal power and natural gas flow transmitted by the branch, respectively.

Further, the step S2 further includes: the nodes are firstly classified according to different node types in the integrated energy system, including: photovoltaic device nodes, gas turbine nodes, electric boiler nodes, gas boiler nodes, heat load nodes, superior power grid access nodes, electric load nodes, natural gas pipeline access nodes, natural gas load nodes, storage battery nodes and the like; and a node connection matrix A is generated according to the network topology structure of the integrated energy system;

$$A = ( \begin{matrix}{n}_{1} & {n}_{2} \\ … & … \\ {n}_{i} & {n}_{j}\end{matrix} )$$

where each row represents a pair of node connections, the first column represents the energy outflow nodes in the integrated energy system, the second column represents the energy inflow nodes, and the matrix A contains all the node connections in the system.

Further, the step S3 includes the following sub-steps:
S31, a graph neural network structure with a graph convolutional network as a core is adopted for processing devices in the integrated energy system and the interrelationship therebetween. For example, each device in the integrated energy system is regarded as a node in the graph, and a physical connection (i.e., a branch) between the devices is regarded as an edge:

$${n}_{i} ∈ N , {e}_{i , j} ∈ E$$

where ηᵢ represents a node represented by a device in the integrated energy system; N represents a set constituted by all nodes; e_{i,j} represents an edge represented by a branch between adjacent nodes i,j in the integrated energy system; and E represents a set constituted by all edges.

S32, a feature vector is assigned to each node for representing a state variable and control strategy of the node; the node determines the feature vector V according to a state variable and a control variable of the corresponding device:

$$V = [ \begin{matrix}{P}_{in} & {P}_{out} & {Q}_{in} & {Q}_{out} & {G}_{in} & {G}_{out} & SOC & X\end{matrix} ]$$

where Pᵢₙ and Pₒᵤₜ represent electric powers that are input into and output from the node, respectively; Qᵢₙ and Qₒᵤₜ represent thermal powers that are input into and output from the node, respectively; Gᵢₙ and Gₒᵤₜ represent natural gas flows that are input into and output from the node, respectively; SOC represents a battery capacity of the node; X is a node start-stop state, indicating whether the node accesses the network, X=0, indicates that the node does not access the graph convolutional network, and X=1 indicates that the node accesses the graph convolutional network.

Each node sets the values of the state variable and the control variable according to a current state and an adopted control strategy, and 0 is assigned to a corresponding position for the node that does not contain a certain variable, and this value is ignored in subsequent processing.

Considering the difference in data scale of different variables in the feature vector, the original data is preprocessed first, and the convergence speed of the model is improved by normalization:

$${V}_{m , z} = \frac{{V}_{m} - μ}{σ}$$

where Vₘ represents a variable value in the feature vector; V_{m,z} represents the variable value normalized by a Z score; and M and a represent the mean and standard deviation of the data set where this variable is located, respectively.
S33, a weight coefficient is assigned to each edge for representing an attribute of each branch; because the branch characteristics in different energy flow networks are different, a simple feedforward fully connected neural network may be used to learn branch characteristics and output an edge weight coefficient Wₑ of a uniform order.
S34, the feature vector of each node is updated by feature fusion of adjacent nodes.

$${V}_{i , z}^{l + 1} = α ( {\sum }_{j ∈ {N}_{i}} {e}_{i , j}^{l} {W}^{l} {V}_{j , z}^{l} + {b}^{l} )$$

where V_{i,z}^{l+1} represents the feature vector of a node i at a next layer; Nᵢ is a set of nodes adjacent to the node i, including the node i itself; V_{j,z}^{l} represents a feature vectors of a node j at a current layer; e_{i,j}^{l} represents an edge weighted value between nodes i,j; W^{l} and b^{l} represent learnable weight matrix and bias coefficient of the current layer; a represents an activation function; and ReLU function is selected except for a last layer, and a linear activation function is selected for the last layer.
S35, a new feature vector is reset for each node after completing the feature fusion of nodes, and step S34 is repeated until a network computing of all layers is completed and the construction of the deep graph neural network model is realized. With feature fusion, the feature vector of a specific position is not only influenced by the feature vectors of other positions of the same node, the feature vectors of the same position at a last moment, but also by the feature vectors of the same position and other positions of adjacent nodes. That is, the state of a certain device is not only affected by the input and output of various energy flows, but also affected by its own state at a last moment. For example, the operation state of a generator is affected by the input power demand, fuel supply and the state of adjacent transformers. Its current output is also be affected by state parameters such as rotational speed, power generation and temperature. In addition, with multi-layer feature fusion, the features of nodes can capture information from distant neighbors, further enhancing the interaction between different features.

Further, the step S4 includes the following steps:
S41, a prediction error loss term [symbol] _{GCN} of the deep graph neural network is calculated:

$${ℒ}_{GCN} = \frac{1}{{ψ}_{N}} {\sum }_{i = 1}^{{ψ}_{N}} {\vert {V}_{i} ( t + 1 ) - {V}_{i} \vert}^{2}$$

where ψ_{N} is a number of elements contained in a set of device nodes; and Vᵢ(t+1) and V₁ [symbol] are a predicted value and an actual value of the feature vector of the node i at a next moment, respectively.

Further, the step S42 of calculating a target loss term of optimization control of the integrated energy system further includes the following sub-sub-steps:
S421, an energy cost is calculated:

$${ℒ}_{Cost , en} = {C}_{E} + {C}_{NG}$$

where [symbol] _{Cost,en} represents the energy cost of the integrated energy system, C_{E} represents a transaction cost between the integrated energy system and a superior power grid; and C_{NG} represents a transaction cost between the integrated energy system and a natural gas company;

$${C}_{E} = {P}_{E} ( t + 1 ) \cdot {Pr}_{E} ( t + 1 )$$

where Pr_{E}(t+1) represents a price of electricity purchased from the superior power grid at the next moment, and P_{E}(t+1) represents the electric power exchange between the integrated energy system and the superior power grid at the next moment;

$${C}_{NG} = {G}_{NG} ( t + 1 ) \cdot {Pr}_{NG} ( t + 1 )$$

where Pr_{NG}(t+1) represents a price of natural gas purchased from the natural gas company at the next moment; and G_{NG}(t+1) represents the flow of natural gas purchased by the integrated energy system from the natural gas company at the next moment.
S422, the device operation and shutdown maintenance costs are calculated:

$${ℒ}_{Cost , eq} = {\sum }_{j = 1}^{3} {\sum }_{i ∈ N} ( {xC}_{op} + ( 1 - x ) {C}_{do} )$$

where [symbol] _{Cost,eq} represents an energy device operation and shutdown maintenance cost, j represents three energy flows, including electricity, heat and gas; and x represents the start-stop state of the device;

$${C}_{op} = {C}_{1} {P}_{j} ( t + 1 ) + {C}_{2}$$

where Cₒₚ represents an device capacity and operating cost; Pⱼ(t+1) represents the power of the energy flow j produced by the device at the next moment; and C₁ and C₂ represent a capacity cost coefficient and an operation cost, respectively;

$${C}_{do} = {C}_{3} {P}_{j , max}$$

where C_{do} represents an device shutdown maintenance cost, P_{j,max} represents an upper power limit of the energy flow j produced by the device; and C₃ represents a downtime maintenance cost coefficient.
S423, an optimization control target loss term is calculated:

$${ℒ}_{Cost} = {ℒ}_{Cost , en} + {μ}_{eq} {ℒ}_{Cost , eq}$$

where [symbol] _{Cost} represents the optimization control target loss term of the integrated energy system; and μ_{eq} represents a weight coefficient of the energy device operation and shutdown maintenance cost.
S43, a constraint loss term of the integrated energy system is calculated.

The constraints of an integrated energy system model are transformed into constraint loss terms, including equality constraints, inequality constraints and 0-1 constraints; and for the equality constraints, an original mathematical model is rewritten into a form of a mismatch quantity:

$$f ( {x}_{1} , {x}_{2} … ) = 0 , f ∈ F$$

where F represents a set of all equality constraints in the integrated energy system model; x₁, x₂ . . . represents each parameter in an original equality constraint; and the loss term [symbol] _{eqc} of the equality constraint may be expressed as:

$${ℒ}_{eqc} = f ( {x}_{1} , {x}_{2} … )$$

where [symbol] _{eqc} represents an equality constraint loss item.

For the inequality constraints, a loss term [symbol] _{iec} of the inequality constraints is expressed as:

$${ℒ}_{iec} = Max ( 0 , {P}_{i} ( t ) - {P}_{i , max} ) + Max ( 0 , {P}_{i , min} - {P}_{i} ( t ) )$$

where Pᵢ(t) represents a power exchange size of energy device or branch i; and P_{i,max} and P_{i,min} represent an upper limit and a lower limit of the power exchange of the device or branch i, respectively.

For the 0-1 constraints, a loss term [symbol] ₀₁ of the 0-1 constraints is expressed as:

$${ℒ}_{01} = {x}_{i} ( {x}_{i} - 1 )$$

where xᵢ represents the start-stop state of the energy device i; and a constraint condition loss term [symbol] _{con} of the integrated energy system is expressed as:

$${ℒ}_{con} = {μ}_{eqc} {ℒ}_{eqc} + {μ}_{iec} {ℒ}_{iec} + {ℒ}_{01}$$

where μ_{eqc} and μ_{iec} represent the cost weight coefficients of an equality constraint and an inequality constraint, respectively.
S44, a total loss function of the deep graph neural network is calculated:

$$ℒ = {ℒ}_{GCN} + {μ}_{Cost} {ℒ}_{Cost} + {μ}_{con} {ℒ}_{con}$$

where [symbol] represents a total loss function of the deep graph neural network; and μ_{Cost} and μ_{con} represent the weight coefficients of a cost term and a constraint condition term, respectively.

Further, the step S5 further includes the following steps:

The physical-informed neural network model is trained according to the historical operation data, and a total loss of the deep graph neural network is calculated until the prediction accuracy of the model meets requirements, which can be used for the optimization control of the integrated energy system. In the concrete optimization, the control system firstly collects the physical parameters of each node in the system in real time by deploying various sensors, including illumination intensity, generator power output, hot water demand, gas flow and state information of energy storage device. The collected data are filtered and standardized to ensure the quality and consistency of the data, and then input into the model for processing. Considering the climate change and user demand fluctuation in different time periods, the model can automatically adjust the operation strategy of each energy source node. In the case of sufficient illumination, the model gives priority to photovoltaic power generation and optimizes the charging and discharging strategy of the battery, thus maximizing the utilization of electric energy. In terms of device regulation, the model can optimize the operation mode of the hot water boiler and electric heating device in real time. By monitoring the heat demand of users in real time, the system automatically adjusts the hot water output of the boiler to meet the changing demand and reduce the energy waste caused by excessive production. In addition, the regulation of gas flow is also included in the optimization scope. The model adjusts the working state of the gas generator according to the changes of the power grid load and gas demand, so as to achieve load balance and stable energy supply. With the ability of the graph neural network, the model may capture complex nonlinear relations, thus enhancing the adaptability of the system under different operating conditions. The model can analyze the state changes of each node in real time, quickly identify the abnormal situation in the system and make a response.

The present disclosure has the following beneficial effects:

According to the present disclosure, a physical-informed neural network model is established based on an integrated energy system model, a physical-informed neural network loss function is constructed by combining a deep graph neural network prediction error loss term, an optimization control target loss term and a constraint condition loss term, and the neural network model is trained by using the physical-informed neural network loss function, so that the optimization control of the operation state of the integrated energy system can be realized, and a new theoretical support is provided for the efficient operation of the industrial integrated energy system. According to the present disclosure, the optimization control of the state of the integrated energy system is realized in a parallel mode of data driving and physical modeling, so that effective countermeasures can be taken to the influence of the uncertainty of renewable energy and unexpected situations on the energy system, and the safe and stable operation of the integrated energy system is guaranteed.

### BRIEF DESCRIPTION OF DRAWINGS

FIG. 1 is the main steps of the method of the present disclosure.

FIG. 2 is a schematic diagram of the network topology of an integrated energy system.

### DESCRIPTION OF EMBODIMENTS

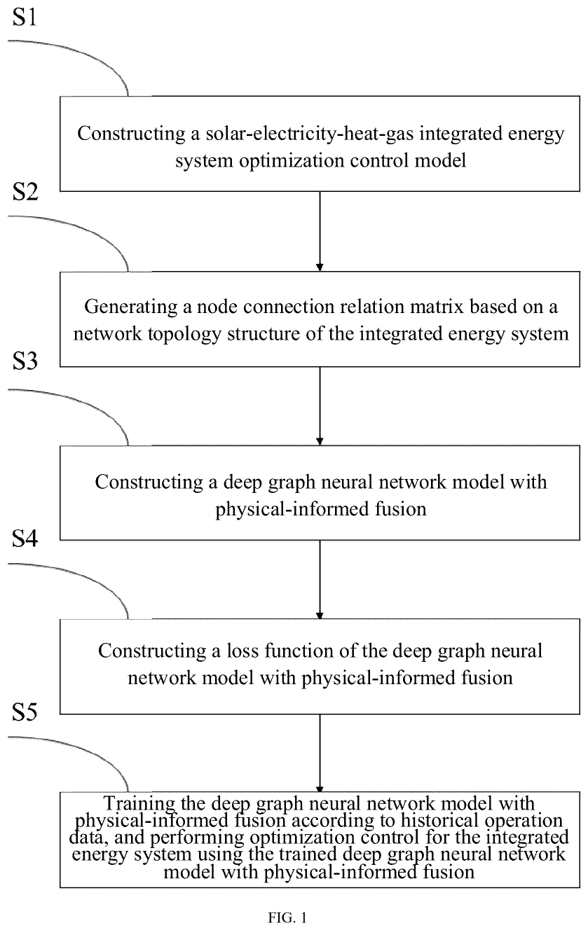

As shown in FIG. 1, a control optimization method for an integrated energy system based on a physical-informed neural network of the present disclosure includes the following steps:
S1, a solar-electricity-heat-gas integrated energy system optimization control model is constructed, including the following sub-steps:
S11, a power generation model of a photovoltaic device and corresponding constraint conditions are established:

$${P}_{PV} ( t ) = G ( i ) A {η}_{PV} {η}_{inv}$$

where P_{PV}(t) represents a generated power of the photovoltaic device at a current moment; G(t) represents the illuminance at the current moment; A represents a photovoltaic panel area; and η_{PV} and ηᵢₙᵥ represent a photovoltaic panel efficiency and an inverter efficiency, respectively;

$$0 < {P}_{PV} ( t ) < {P}_{PV , max}$$

where P_{PV,max} represents the upper limit of the generated power of the photovoltaic device.
S12, an output model of a cogeneration device is established, further including the following sub-sub-steps:
S121, a power model (including a power generation model and an output thermal power model) of a gas turbine and the corresponding constraint conditions are established:

The power generation model and corresponding constraint conditions are as follows:

$${P}_{GT} ( t ) = {G}_{GT} ( t ) {q}_{NG} {η}_{GT}$$

where P_{GT}(t) represents a generated power of the gas turbine at a current moment; G_{GT}(t) represents a natural gas flow into the gas turbine at the current moment; q_{NG} represents a low calorific value of natural gas; and η_{GT} represents a power generation efficiency of the gas turbine;

$${P}_{GT , min} < {P}_{GT} ( t ) < {P}_{GT , max}$$

where P_{GT,max} and P_{GT,min} represent the upper and lower limits of the generated power of the gas turbine, respectively.

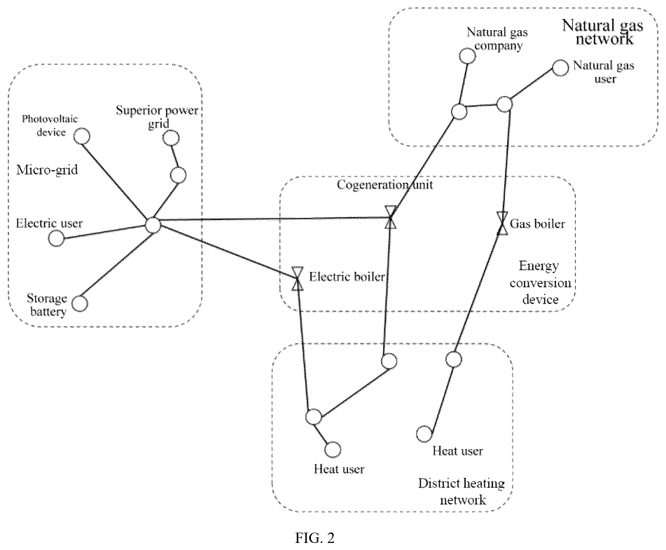

The output thermal power model and corresponding constraint conditions are:

$${Q}_{GT ( f )} = {G}_{GT} ( t ) {q}_{NG} ( 1 - {η}_{GT} )$$

where Q_{GT}(t) represents the output thermal power of the gas turbine at the current moment;

$${Q}_{GT , min} < {Q}_{GT} ( t ) < {Q}_{GT , max}$$

where Q_{GT,max} and Q_{GT,min} represent the upper and lower limits of the output thermal power of the gas turbine, respectively.
S122, a thermal power model of a waste heat boiler and the corresponding constraint conditions are established.

$${Q}_{HRSG} ( t ) = {Q}_{GT} ( t ) {η}_{HRSG}$$

where Q_{HRSG}(t) represents an output thermal power of the waste heat boiler at a current moment; η_{HRSG} represents a heat exchange efficiency of the waste heat boiler;

$${Q}_{HRSG , min} < {Q}_{HRSG} ( t ) < {Q}_{HRSG , max}$$

where Q_{HRSG,max} and Q_{HRSG,min} represent the upper and lower limits of the output thermal power of the waste heat boiler, respectively.
S13, a thermal power model of an electric boiler and the corresponding constraint conditions are established:

$${Q}_{EB} ( t ) = {P}_{EB} ( t ) {η}_{EB}$$

where Q_{EB}(t) represents an output thermal power of the electric boiler at a current moment; P_{EB}(t) represents the electric power consumed by the electric boiler at the current moment; η_{EB} represents an electrothermal conversion efficiency of the electric boiler;

$${Q}_{EB , min} < {Q}_{EB} ( t ) < {Q}_{EB , max}$$

where Q_{EB,max} and Q_{EB,min} represent the upper and lower limits of the output thermal power of the electric boiler, respectively.
S14, a thermal power model of a gas boiler and the corresponding constraint conditions are established:

$${Q}_{GB} ( t ) = {G}_{GB} ( t ) {q}_{NG} {η}_{GB}$$

where Q_{GB}(t) represents an output thermal power of the gas boiler at a current moment; G_{GB}(t) represents a natural gas flow into the gas boiler at the current moment; η_{GB} represents the gas-heat conversion efficiency of the gas boiler;

$${Q}_{GB , min} < {Q}_{GB} ( t ) < {Q}_{GB , max}$$

where Q_{GB,max} and Q_{GB,min} represent the upper and lower limits of the output thermal power of the gas boiler, respectively.
S15, a thermal power model of a heat exchanger and the corresponding constraint conditions are established:

$${Q}_{HE} ( t ) = {Q}_{HE}^{′} ( t ) {η}_{H}$$

where Q_{HE}(t) represents an output thermal power of the heat exchanger at a current moment; Q′_{HE}(t) represents tan input thermal power of the heat exchanger at the current moment; η_{H} represents a heat exchange efficiency of the heat exchange device;

$${Q}_{HE , min} < {Q}_{HE} ( t ) < {Q}_{HE , max}$$

where Q_{HE,max} and Q_{HE,min} represent the upper and lower limits of the output thermal power of the heat exchanger, respectively.
S16, an electric energy storage model of a storage battery and the corresponding constraint conditions are established:

$$SOC = SOC ( t - 1 ) + {η}_{c} {P}_{char} ( t ) - \frac{{P}_{dis} ( t )}{{η}_{d}}$$

where SOC(t) and SOC(t−1) represent the capacities of the battery at a current moment and a last moment, respectively; P_{char}(t) and P_{dis}(t) represent the charging and discharging powers of the storage battery, respectively; q_{c} and η_{d} represent the charging and discharging efficiencies of the storage battery, respectively;

$${SOC}_{min} < SOC ( t ) , SOC ( t - 1 ) < {SOC}_{max}$$

$${P}_{SOC , min} < {P}_{char} , {P}_{dis} < {P}_{SOC , max}$$

$${P}_{char} {P}_{dis} ( t ) = 0$$

where SOCₘₐₓ and SOCₘᵢₙ represent the upper and lower limits of the capacity of the storage battery, respectively, and P_{SOC,max} and P_{SOC,min} represent the upper and lower limits of the charging and discharging powers of the storage battery, respectively.
S17, an equilibrium equation of each energy flow network is established, specifically including the following sub-sub-steps:
S171, a power equilibrium equation of a power grid is established:

$${P}_{PV} ( t ) + {P}_{GT} ( t ) + {P}_{dis} ( t ) + {P}_{E} ( t ) = {L}_{E} ( t ) + {P}_{EB} ( t ) + {P}_{char} ( t )$$

where P_{E}(t) represent the electric power exchange between the integrated energy system and a superior power grid, and its value is positive when the integrated energy system purchases electricity from the power grid, and otherwise it is negative; L_{E}(t) represents the electric power provided by the integrated energy system to users.
S172, a power equilibrium equation of a heat supply network is established:

$${Q}_{HRSG} ( t ) + {Q}_{EB} ( t ) + {Q}_{GB} ( t ) = \frac{{L}_{H} ( t )}{{η}_{H}}$$

where L_{H}(t) represents a thermal power provided by the integrated energy system to users.
S173, a flow equilibrium equation of a gas network is established:

$${G}_{GT} ( t ) + {G}_{GB} ( t ) + {L}_{NG} ( t ) = {G}_{NG} ( t )$$

where L_{NG}(t) represents a natural gas flow provided by the integrated energy system to users; G_{NG}(t) represents the flow of natural gas purchased by the integrated energy system from a natural gas company.
S18, branch constraint conditions of the integrated energy system are established:

$$0 < {P}_{br} ( t ) < {P}_{br , max}$$

$$0 < {Q}_{br} ( t ) < {Q}_{br , max}$$

$$0 < {G}_{br} ( t ) < {G}_{br , max}$$

where P_{br}(t), Q_{br}(t) and G_{br}(t) represent the electric power, thermal power and natural gas flow of any branch at the current moment, respectively; P_{br,max}, Q_{br,max} and G_{br,max} represent the upper limits of the electric power, thermal power and natural gas flow transmitted by the branch, respectively.
S2, a node connection relation matrix is generated based on a network topology structure (as shown in FIG. 2) of the integrated energy system, which is specifically as follows: the nodes are firstly classified according to different node types in the integrated energy system, including: photovoltaic device nodes, gas turbine nodes, electric boiler nodes, gas boiler nodes, heat load nodes, superior power grid access nodes, electric load nodes, natural gas pipeline access nodes, natural gas load nodes, storage battery nodes and the like; a node connection matrix A is generated according to the network topology structure of the integrated energy system;

$$A = ( \begin{matrix}{n}_{1} & {n}_{2} \\ … & … \\ {n}_{i} & {n}_{j}\end{matrix} )$$

where each row represents a pair of node connections, the first column represents the energy outflow nodes in the integrated energy system, the second column represents the energy inflow nodes, and the matrix A contains all the node connections in the system.
S3, a deep graph neural network model with physical-informed fusion is constructed based on the solar-electricity-heat-gas integrated energy system optimization control model constructed in the step S1 and the node connection relation matrix constructed in the step S2, further including the following sub-steps:
S31, a graph neural network structure with a graph convolutional network as a core is adopted for processing devices in the integrated energy system and the interrelationship therebetween. For example, each device in the integrated energy system is regarded as a node in the graph, and a physical connection between the devices is regarded as an edge:

$${n}_{i} ∈ N , {e}_{i , j} ∈ E$$

where nᵢ represents a node represented by a device in the integrated energy system; N represents a set constituted by all nodes; e_{i,j} represents an edge represented by a branch between adjacent nodes i,j in the integrated energy system; and E represents a set constituted by all edges.

S32, a feature vector is assigned to each node for representing a state variable and control strategy of the node; the node determines the feature vector V according to a state variable and a control variable of the corresponding device:

$$V = [ \begin{matrix}{P}_{in} & {P}_{out} & {Q}_{in} & {Q}_{out} & {G}_{in} & {G}_{out} & SOC & X\end{matrix} ]$$

where Pᵢₙ and Pₒᵤₜ represent electric powers that are input into an output from the node, respectively; Qᵢₙ and Qₒᵤₜ represent thermal powers that are input into and output from the node, respectively; Gᵢₙ and Gₒᵤₜ represent natural gas flows that are input into and output from the node, respectively; SOC represents a battery capacity of the node; X is a node start-stop state, indicating whether the node accesses the network, 0 means no access, and 1 means access.

Each node sets the values of the state variable and the control variable according to a current state and an adopted control strategy, and 0 is assigned to a corresponding position for the node that does not contain a certain variable, and this value is ignored in subsequent processing.

Considering the difference in data scale of different variables in the feature vector, the original data is preprocessed first, and the convergence speed of the model is improved by normalization:

$${V}_{m , z} = \frac{{V}_{m} - μ}{σ}$$

where Vₘ represents a variable value in the feature vector; V_{m,z} represents the variable value normalized by a Z score; and μ and σ represent the mean and standard deviation of the data set where this variable is located, respectively.
S33, a weight coefficient is assigned to each edge for representing an attribute of each branch; because the branch characteristics in different energy flow networks are different, a simple feedforward fully connected neural network may be used to learn branch characteristics and output an edge weight coefficient Wₑ of a uniform order.
S34, the feature vector of each node is updated by feature fusion of adjacent nodes;

$${V}_{i , z}^{l + 1} = α ( {\sum }_{j ∈ {N}_{i}} {e}_{i ,}^{l} {W}^{l} {V}_{j , z}^{l} + {b}^{l} )$$

where V_{i,z}^{l+1} represents the feature vector of a node i at a next layer; Nᵢ is a set of nodes adjacent to the node i, including the node i itself; V_{j,z}^{l} represents a feature vectors of a node j at a current layer; e_{i,j}^{l} represents an edge weighted value between nodes i,j; W^{l} and b^{l} represent learnable weight matrix and bias coefficient of the current layer; a represents an activation function; ReLU function is selected except for a last layer, and a linear activation function is selected for the last layer.
S35, a new feature vector is reset for each node after completing the feature fusion of nodes, and step S34 is repeated until a network computing of all layers is completed and the construction of the deep graph neural network model is realized. With feature fusion, the feature vector of a specific position is not only influenced by the feature vectors of other positions of the same node, the feature vectors of the same position at a last moment, but also by the feature vectors of the same position and other positions of adjacent nodes. That is, the state of a certain device is not only affected by the input and output of various energy flows, but also affected by its own state at a last moment. For example, the operation state of a generator is affected by the input power demand, fuel supply and the state of adjacent transformers. Its current output is also be affected by state parameters such as rotational speed, power generation and temperature. In addition, with multi-layer feature fusion, the features of nodes can capture information from distant neighbors, further enhancing the interaction between different features.
S4, a loss function of the deep graph neural network model with physical-informed fusion is constructed, further including the following sub-steps:
S41, a prediction error loss term [symbol] _{GCN} of the deep graph neural network is calculated:

$${ℒ}_{GCN} = \frac{1}{{ψ}_{N}} {\sum }_{i = 1}^{{ψ}_{N}} {\vert {V}_{i} ( t + 1 ) - {V}_{1} \vert}^{2}$$

where ψ_{N} is the number of elements contained in a set of device nodes; Vᵢ(t+1) and Vₗ [symbol] are a predicted value and an actual value of the feature vector of the node i at a next moment, respectively.
S42, a target loss term of optimization control of the integrated energy system is calculated, further including the following sub-sub-steps:
S421, an energy cost is calculated:

$${ℒ}_{Cost , en} = {C}_{E} + {C}_{NG}$$

where [symbol] _{Cost,en} represents the energy cost of the integrated energy system, C_{E} represents a transaction cost between the integrated energy system and a superior power grid; and C_{NG} represents a transaction cost between the integrated energy system and a natural gas company;

$${C}_{E} = {P}_{E} ( t + 1 ) \cdot {Pr}_{E} ( t + 1 )$$

where Pr_{E} (t+1) represents a price of electricity purchased from the superior power grid at the next moment, and P_{E}(t+1) represents the electric power exchange between the integrated energy system and the superior power grid at the next moment;

$${C}_{NG} = {G}_{NG} ( t + 1 ) \cdot {Pr}_{NG} ( t + 1 )$$

where Pr_{NG}(t+1) represents a price of natural gas purchased from the natural gas company at the next moment; and G_{NG}(t+1) represents the flow of natural gas purchased by the integrated energy system from the natural gas company at the next moment.
S422, the device operation and shutdown maintenance costs are calculated:

$${ℒ}_{Cost , eq} = {\sum }_{j = 1}^{3} {\sum }_{i ∈ N} ( {xC}_{op} + ( 1 - x ) {C}_{do} )$$

where [symbol] _{Cost,eq} represents an energy device operation and shutdown maintenance cost, j represents three energy flows, including electricity, heat and gas; and x represents the start-stop state of the device;

$${C}_{op} = {C}_{1} {P}_{j} ( t + 1 ) + {C}_{2}$$

where Cₒₚ represents an device capacity and operating cost; Pⱼ(t+1) represents the power of the energy flow j produced by the device at the next moment; and C₁ and C₂ represent a capacity cost coefficient and an operation cost, respectively;

$${C}_{do} = {C}_{3} {P}_{j , max}$$

where C_{do} represents an device shutdown maintenance cost, P_{j,max} represents an upper power limit of the energy flow j produced by the device; and C₃ represents a downtime maintenance cost coefficient.
S423, an optimization control target loss term is calculated:

$${ℒ}_{Cost} = {ℒ}_{Cost , en} + {μ}_{eq} {ℒ}_{Cost , eq}$$

where [symbol] _{Cost} represents the optimization control target loss term of the integrated energy system; μ_{eq} represents a weight coefficient of the energy device operation and shutdown maintenance cost.
S43, a constraint loss term of the integrated energy system is calculated. The constraints of an integrated energy system model are transformed into constraint loss terms, including equality constraints, inequality constraints and 0-1 constraints; and for the equality constraints, an original mathematical model is rewritten into a form of a mismatch quantity:

$$f ( {x}_{1} , {x}_{2} … ) = 0 , f ∈ F$$

where F represents a set of all equality constraints in the integrated energy system model; x₁, x₂ . . . represents each parameter in an original equality constraint; and the loss term [symbol] _{eqc} of the equality constraint may be expressed as:

$${ℒ}_{eqc} = f ( {x}_{1} , {x}_{2} … )$$

where [symbol] _{eqc} represents an equality constraint loss item.

For the inequality constraints: [symbol] _{iec}=Max(0, Pᵢ(t)−P_{i,max})+Max(0, P_{i,min}−Pᵢ(t)).

where [symbol] _{iec} represents an inequality constraint condition term; Pᵢ(t) represents a power exchange size of energy device or branch i; and P_{i,max} and P_{i,min} represent an upper limit and a lower limit of the power exchange of the device or branch i, respectively;

For the 0-1 constraints: [symbol] ₀₁=xᵢ(xᵢ−1).

where [symbol] ₀₁ represents a 0-1 constraint item; xᵢ represents the start-stop state of the energy device i;

$${ℒ}_{con} = {μ}_{eqc} {ℒ}_{eqc} + {μ}_{iec} {ℒ}_{iec} + {ℒ}_{01}$$

where [symbol] _{con} represents a constraint condition loss term of the integrated energy system; μ_{eqc} and μ_{iec} represent the cost weight coefficients of an equality constraint and an inequality constraint, respectively.
S44, a total loss function of the deep graph neural network is calculated:

$$ℒ = {ℒ}_{GCN} + {μ}_{Cost} {ℒ}_{Cost} + {μ}_{con} {ℒ}_{con}$$

where [symbol] represents a total loss function of the neural network; μ_{Cost} and μ_{con} represent the weight coefficients of a cost term and a constraint condition term, respectively.

S5, the physical-informed neural network model is trained according to the historical operation data, and a total loss of the deep graph neural network is calculated until the prediction accuracy of the model meets requirements. When the external environment variables contained in the integrated energy system model change, such as the electricity price of the superior power grid changes, the solar illumination intensity changes or new energy users access, the deep graph neural network model with physical-informed fusion gives control strategies through the physical-informed neural network, so that the current state variables of each node can be transformed into the state at the next moment after being fused and updated by the characteristics of the graph neural network, and the goal of system optimization is thus achieved.

In a smart grid, the model improves the efficiency and reliability of power distribution by collaborative work of multiple layers of device and systems. The specific steps are as follows: first, the sensors deployed in the power grid monitor multiple parameters in real time, including the current, voltage and power factor of the substation, as well as the operating state (such as load, temperature, etc.) of each generator set. Data are collected at a high frequency and transmitted to a control center to ensure timely reflection of the state of the power grid; subsequently, in the data center, data cleaning and standardization tools are used to remove noise and abnormal values to form a comprehensive power grid state view; subsequently the model receives the complete state of the power grid and obtains the output result, and generates an optimization control strategy based on the output of the model. Specifically, during a peak load period, the model will give priority to dispatching low-cost renewable energy generators (such as wind power and photovoltaic generators) and dynamically adjust the output power of generators to meet the demand. At the same time, by analyzing real-time data, the model is able to predict future load changes and make scheduling adjustments in advance; finally, the control system converts the output results into specific control instructions through an SCADA system to directly control the power output of generators, the load allocation of substations and the load balance of transmission lines, thus ensuring the stability and efficient operation of the power grid.

In the industrial production environment, the model can improve the operation efficiency of device and reduce energy consumption by coordinating the operation outputs of device in all links. The specific implementation steps are as follows: real-time data such as temperature, pressure, flow and energy consumption are collected from sensors installed on industrial device (such as boilers, cooling towers and compressors) and transmitted to the central control system; the control system integrates the real-time collected data, and carries out noise filtering, missing value filling and standardization to ensure the consistency and reliability of the data; the integrated data are input into the model and a relationship diagram between devices is constructed; based on real-time data, the model analyzes the running state between devices and identifies the optimization potential. For example, in a certain period of time, if the boiler load is too high, the model will suggest reducing the fuel supply of the boiler and improving the operating efficiency of the cooling tower accordingly to keep the system stable; the control system converts the control strategy into specific control instructions, and directly adjusts the running state of each device through PLC. The fuel supply of the boiler, the water flow of the cooling tower and the operation mode of the compressor can all respond to the optimization results of the model in real time to ensure the efficient operation of the whole production process.

In an intelligent community, the model improves the overall energy management efficiency by collaboration of various energy resources in the community. The specific implementation steps are as follows: various sensors are installed in the community to monitor the flow states of energy sources such as electricity, heat and gas, and the data are transmitted to a central control platform; the control platform preprocesses all kinds of data to ensure the consistency and accuracy of the data; after processing, a real-time model of energy flow in the community is formed; the preprocessed data are input into a graph neural network, and a topology diagram of various energy nodes (such as battery energy storage, water heater and gas generator) in the community is constructed; the model analyzes the energy demand in the community in real time and optimizes the operation strategy of each node. For example, priority is given to the use of renewable energy for hot water supply, and the operating state of the gas generator is adjusted according to the power grid load to achieve load balance and reduce energy consumption; with the intelligent control system, the control platform transforms the optimal scheduling strategy into specific operation instructions to directly control the operation of each device, so as to respond to the change of energy demand in the community and ensure the efficient and sustainable utilization of community energy.

What is claimed is:

1. An optimization control method for an integrated energy system based on a physical-informed neural network, comprising following steps:
step S1, constructing a solar-electricity-heat-gas integrated energy system optimization control model;
step S2, generating a node connection relation matrix based on a network topology structure of the integrated energy system;
step S3, constructing a deep graph neural network model with physical-informed fusion based on the solar-electricity-heat-gas integrated energy system optimization control model constructed in the step S1 and the node connection relation matrix constructed in the step S2;
wherein the step S3 comprises the following sub-steps:
sub-step S31, adopting a graph neural network structure with a graph convolutional network as a core for processing devices in the integrated energy system and an interrelationship therebetween; and regarding each device in the integrated energy system as a node in a graph, and regarding a physical connection between the devices as an edge:
$${n}_{i} ∈ N , {e}_{i , j} ∈ E$$
where nᵢ represents a node represented by a device in the integrated energy system; N represents a set constituted by all nodes; e_{i,j} represents an edge represented by a branch between adjacent nodes i,j in the integrated energy system; and E represents a set constituted by all edges;
sub-step S32, assigning a feature vector to each node for representing a state variable and control strategy of the node; and determining, by the node, the feature vector V based on a state variable and a control variable of a corresponding device:
$$V = [ \begin{matrix}{P}_{in} & {P}_{out} & {Q}_{in} & {Q}_{out} & {G}_{in} & {G}_{out} & SOC & X\end{matrix} ]$$
where Pᵢₙ and Pₒᵤₜ represent electric powers that are input into and output from the node, respectively; Qᵢₙ and Qₒᵤₜ represent thermal powers that are input into and output from the node, respectively; Gᵢₙ and Gₒᵤₜ represent natural gas flows that are input into and output from the node, respectively; SOC represents a battery capacity of the node; X is a node start-stop state, indicating whether the node accesses the graph convolutional network, wherein X=0 indicates that the node does not access the graph convolutional network, and X=1 indicates that the node accesses the graph convolutional network; and
configuring, by the each node, values of the state variable and the control variable based on a current state and an adopted control strategy, and assigning 0 to a corresponding position for the node that does not comprise a variable;
sub-step S33, assigning a weight coefficient to each edge for representing an attribute of each branch; and learning branch characteristics using a feedforward fully connected neural network and outputting an edge weight coefficient Wₑ of a uniform order;
sub-step S34, updating the feature vector of each node by feature fusion of adjacent nodes;
$${V}_{i , z}^{l + 1} = α ( {\sum }_{j ∈ {N}_{i}} {e}_{i , j}^{l} {W}^{l} {V}_{j , z}^{l} + {b}^{l} )$$
where V_{i,z}^{l+1} represents the feature vector of a node i at a next layer; Nᵢ represents a set of nodes adjacent to the node i, comprising the node i; V_{j,z}^{l} represents a feature vectors of a node j at a current layer; e_{i,j}^{l} represents an edge weighted value between nodes i,j; W¹ and b^{l} represent learnable weight matrix and bias coefficient of the current layer; a represents an activation function; and ReLU function is selected except for a last layer, and a linear activation function is selected for the last layer; and
sub-step S35, resetting a new feature vector for each node after completing the feature fusion of nodes, and repeating the step S34 until a network computing of all layers is completed, to realize a construction of the deep graph neural network model;
step S4, constructing a loss function of the deep graph neural network model with physical-informed fusion; and
step S5, training the deep graph neural network model with physical-informed fusion according to historical operation data, and performing an optimization control for the integrated energy system using the trained deep graph neural network model with physical-informed fusion, wherein said optimization control further comprises:
collecting physical parameters of each node in the integrated energy in real time, and filtering and standardizing the collected physical parameters to ensure a quality and consistency of the physical parameters;
inputting the processed physical parameters, adjusting an operation strategy of each energy node in real time to meet changing needs and environmental conditions; and
prioritizing scheduling of photovoltaic power generation when there is sufficient illumination optimizing a hot water boiler and a gas flow to achieve load balancing and maximize energy efficiency, thereby improving an overall performance of the integrated energy system.

2. The optimization control method for the integrated energy system based on the physical-informed neural network according to claim 1, wherein the step S1 comprises following sub-steps:
sub-step S11, establishing a power generation model of a photovoltaic device and corresponding constraint conditions;
sub-step S12, establishing an output model of a cogeneration device, and a thermal power model of a waste heat boiler and corresponding constraint conditions, wherein the output model of the cogeneration device comprises a power model of a gas turbine and corresponding constraint conditions;
sub-step S13, establishing a thermal power model of an electric boiler and corresponding constraint conditions;
sub-step S14, establishing a thermal power model of gas boiler and corresponding constraint conditions;
sub-step S15, establishing a thermal power model of a heat exchange device and corresponding constraint conditions;
sub-step S16, establishing an electric energy storage model of a storage battery and corresponding constraint conditions;
sub-step S17, establishing a power equilibrium equation of each energy flow network; and
sub-step S18, establishing branch constraint conditions of the integrated energy system.

3. The optimization control method for the integrated energy system based on the physical-informed neural network according to claim 2, wherein the step S2 further comprises: based on the network topology of the integrated energy system, determining connection conditions of internal nodes of each energy flow network and connection conditions between the internal nodes of each energy flow network and an energy conversion device, and generating a node connection matrix.

4. The optimization control method for the integrated energy system based on the physical-informed neural network according to claim 1, wherein the step S4 comprises following sub-steps:
sub-step S41, calculating a prediction error loss term [symbol] _{CN} of the deep graph neural network:
$${ℒ}_{GCN} = \frac{1}{{ψ}_{N}} {\sum }_{i = 1}^{{ψ}_{N}} {\vert {V}_{i} ( t + 1 ) - {V}_{1} \vert}^{2}$$
where ψ_{N} represents a number of elements comprised in a set of device nodes; and Vᵢ(t+1) and Vₗ [symbol] represent a predicted value and an actual value of the feature vector of the node i at a next moment, respectively;
sub-step S42, calculating a target loss term of optimization control of the integrated energy system;
sub-sub-step S421, calculating an energy cost:
$${ℒ}_{Cost , en} = {C}_{E} + {C}_{NG}$$
where [symbol] _{Cost,en} represents the energy cost of the integrated energy system, C_{E} represents a transaction cost between the integrated energy system and a superior power grid; and C_{NG} represents a transaction cost between the integrated energy system and a natural gas company;
$${C}_{E} = {P}_{E} ( t + 1 ) \cdot {Pr}_{E} ( t + 1 )$$
where Pr_{E}(t+1) represents a price of electricity purchased from the superior power grid at the next moment, and P_{E}(t+1) represents the electric power exchange between the integrated energy system and the superior power grid at the next moment;
$${C}_{NG} = {G}_{NG} ( t + 1 ) \cdot {Pr}_{NG} ( t + 1 )$$
where Pr_{NG}(t+1) represents a price of natural gas purchased from the natural gas company at the next moment; and G_{NG}(t+1) represents the flow of natural gas purchased by the integrated energy system from the natural gas company at the next moment;
sub-sub-step S422, calculating device operation and shutdown maintenance costs:
$${ℒ}_{Cost , eq} = {\sum }_{j = 1}^{3} {\sum }_{i ∈ N} ( {xC}_{op} + ( 1 - x ) {C}_{do} )$$
where [symbol] _{Cost,eq} represents an energy device operation and shutdown maintenance cost, j represents three energy flows, comprising electricity, heat and gas; x represents a start-stop state of the device; Cₒₚ represents a device capacity and operation cost; and C_{do} represents a device downtime maintenance cost;
$${C}_{op} = {C}_{1} {P}_{j} ( t + 1 ) + {C}_{2}$$
where Pⱼ(t+1) represents a power of the energy flow j produced by the device at the next moment; and C₁ and C₂ represent a capacity cost coefficient and an operation cost, respectively;
$${C}_{do} = {C}_{3} {P}_{j , max}$$
where P_{j,max} represents an upper power limit of the energy flow j produced by the device; and C₃ represents a downtime maintenance cost coefficient; and
sub-sub-step S423, calculating an optimization control target loss term:
$${ℒ}_{Cost} = {ℒ}_{Cost , en} + {μ}_{eq} {ℒ}_{Cost , eq}$$
where [symbol] _{Cost} represents the optimization control target loss term of the integrated energy system; and μ_{eq} represents a weight coefficient of the energy device operation and shutdown maintenance cost;
sub-step S43, calculating a constraint loss term of the integrated energy system;
wherein a constraints of an integrated energy system model are transformed into constraint loss terms, comprising equality constraints, inequality constraints and 0-1 constraints;
for the equality constraints, rewriting an original mathematical model into a form of a mismatch quantity:
$$f ( {x}_{1} , {x}_{2} … ) = 0 , f ∈ F$$
where F represents a set of all equality constraints in the integrated energy system model; x₁, x₂ . . . represents each parameter in an original equality constraint; and a loss term [symbol] _{eqc} of the equality constraints is expressed as:
$${ℒ}_{eqc} = f ( {x}_{1} , {x}_{2} … )$$
for the inequality constraints, a loss term [symbol] _{iec} of the inequality constraints is expressed as:
$${ℒ}_{iec} = Max ( 0 , {P}_{i} ( t ) - {P}_{i , max} ) + Max ( 0 , {P}_{i , min} - {P}_{i} ( t ) )$$
where Pᵢ(t) represents a power exchange size of an energy device or a branch i; and P_{i,max} and P_{i,min} represent an upper limit and a lower limit of the power exchange of the device or the branch i, respectively;
for the 0-1 constraints, a loss term [symbol] ₀₁ of the 0-1 constraints is expressed as:
$${ℒ}_{01} = {x}_{i} ( {x}_{i} - 1 )$$
where xᵢ represents a start-stop state of the energy device i; and a constraint condition loss term of the integrated energy system is expressed as:
$${ℒ}_{con} = {μ}_{eqc} {ℒ}_{eqc} + {μ}_{iec} {ℒ}_{iec} + {ℒ}_{01}$$
where μ_{eqc} and μ_{iec} represent cost weight coefficients of the equality constraints and the inequality constraints, respectively; and
sub-step S44, calculating a total loss function of the deep graph neural network:
$$ℒ = {ℒ}_{GCN} + {μ}_{Cost} {ℒ}_{Cost} + {μ}_{con} {ℒ}_{con}$$
where [symbol] represents a total loss function of the deep graph neural network; and μ_{Cost} and μ_{con} represent weight coefficients of a cost term and a constraint condition term, respectively.

5. The optimization control method for the integrated energy system based on the physical-informed neural network according to claim 4, wherein the step S5 further comprises:
updating repeatedly and iteratively the feature vector of each node based on the historical operation data, and calculating a total loss of the deep graph neural network until a model prediction accuracy meets requirements for the optimization control of the integrated energy system.
